(19) United States
(12) Patent Application Publication
(10) Pub. No.: US 2024/0178344 A1
(43) Pub. Date: May 30, 2024

(54) ULTRAVIOLET LIGHT EMITTING ELEMENT

(71) Applicant: ASAHI KASEI KABUSHIKI KAISHA, Tokyo (JP)

(72) Inventor: Tomoya YAMADA, Tokyo (JP)

(73) Assignee: ASAHI KASEI KABUSHIKI KAISHA, Tokyo (JP)

(21) Appl. No.: 18/283,346

(22) PCT Filed: Mar. 9, 2022
(86) PCT No.: PCT/JP2022/010402

§ 371 Date: Sep. 21, 2023

(30) Foreign Application Priority Data
Mar. 23, 2021 (JP) 2021-048526

(51) Int. Cl. H01L 33/24; H01L 33/06; H01L 33/32; H01L 33/44

(52) U.S. Cl. CPC H01L 33/24; H01L 33/06; H01L 33/32; H01L 33/44

(57) ABSTRACT

Provided is an ultraviolet light emitting element having a long life. The ultraviolet light emitting element includes a substrate, a nitride semiconductor laminate, and a first electrode and a second electrode in which the nitride semiconductor laminate includes a first semiconductor layer of a first conductivity type, a light emitting mesa structure part disposed on the first semiconductor layer of the first conductivity type, and a protective mesa structure part that is disposed on the first semiconductor layer of the first conductivity type and is spatially separated from the light emitting mesa structure part. The first electrode is disposed on the first semiconductor layer of the first conductivity type, and the second electrode is disposed on the first semiconductor layer of the second conductivity type included in the light emitting mesa structure part.

### TECHNICAL FIELD

The present disclosure relates to an ultraviolet light emitting element.

### BACKGROUND ART

As an ultraviolet light emitting element in related art, for example, a light emitting element in which a part of a nitride semiconductor layer has a mesa structure in order to narrow the current and improve the current density is known (for example, PTL 1).

### CITATION LIST

### Patent Literature

PTL 1: JP 2014-096460 A

### SUMMARY OF INVENTION

### Technical Problem

It is desirable that the life of the ultraviolet light emitting element is further extended, that is, an increase in a drive voltage is suppressed and output deterioration is suppressed even when the ultraviolet light emitting element is continuously energized. However, in the above-described ultraviolet light emitting element, there has been a case where the long life is not sufficient.

An object of the present disclosure is to provide an ultraviolet light emitting element having a long life.

### Solution to Problem

An ultraviolet light emitting element according to one aspect of the present disclosure includes a substrate; a nitride semiconductor laminate disposed on the substrate; and a first electrode and a second electrode, in which the nitride semiconductor laminate includes a first semiconductor layer of a first conductivity type, a light emitting mesa structure part disposed on the first semiconductor layer of the first conductivity type, and a protective mesa structure part that is disposed on the first semiconductor layer of the first conductivity type and is spatially separated from the light emitting mesa structure part, the light emitting mesa structure part includes a second semiconductor layer of the first conductivity type, a first quantum well layer disposed on the second semiconductor layer of the first conductivity type, and a first semiconductor layer of a second conductivity type disposed on the first quantum well layer, the protective mesa structure part includes a third semiconductor layer of the first conductivity type, a second quantum well layer disposed on the third semiconductor layer of the first conductivity type, and a second semiconductor layer of the second conductivity type disposed on the second quantum well layer, the first electrode is disposed on the first semiconductor layer of the first conductivity type, and the second electrode is disposed on the first semiconductor layer of the second conductivity type of the light emitting mesa structure part.

### Advantageous Effects of Invention

According to the present disclosure, an ultraviolet light emitting element having a long life can be realized.

### BRIEF DESCRIPTION OF DRAWINGS

FIG. 1A is a schematic plan view illustrating a planar configuration of an ultraviolet light emitting element according to a first embodiment of the present disclosure;

FIG. 1B is a schematic sectional view illustrating a cross-sectional configuration of the ultraviolet light emitting element of the first embodiment of the present disclosure;

FIG. 2A is a schematic plan view illustrating a planar configuration of an ultraviolet light emitting element in related art;

FIG. 2B is a schematic sectional view illustrating a cross-sectional configuration of the ultraviolet light emitting element in related art;

FIG. 3 is a schematic plan view illustrating a disposition of a protective mesa structure part in the ultraviolet light emitting element of the first embodiment of the present disclosure; and

FIG. 4 is a schematic plan view illustrating another planar configuration of the ultraviolet light emitting element of the first embodiment of the present disclosure.

### DESCRIPTION OF EMBODIMENTS

Hereinafter, the present disclosure will be described through embodiments of the present invention, but the following embodiments do not limit the invention within the scope of claims. In addition, not all combinations of features described in the embodiments are essential for the solution of the invention.

### 1. Embodiments

Hereinafter, an ultraviolet light emitting element according to an embodiment of the present disclosure will be described.

### (1.1) Structure of Ultraviolet Light Emitting Element

An ultraviolet light emitting element according to an embodiment (hereinafter, referred to as the present embodiment) of the present disclosure includes a substrate, a nitride semiconductor laminate disposed on the substrate, a first electrode, and a second electrode.

The nitride semiconductor laminate has a first semiconductor layer of a first conductivity type, a light emitting mesa structure part disposed on the first semiconductor layer of the first conductivity type, and a protective mesa structure part that is disposed on the first semiconductor layer of the first conductivity type and spatially separated from the light emitting mesa structure part.

The light emitting mesa structure part has a second semiconductor layer of the first conductivity type, a first quantum well layer disposed on the second semiconductor layer of the first conductivity type, and a first semiconductor layer of a second conductivity type disposed on the first quantum well layer.

In addition, the protective mesa structure part has a third semiconductor layer of the first conductivity type, a second quantum well layer disposed on the third semiconductor layer of the first conductivity type, and a second semiconductor layer of the second conductivity type disposed on the second quantum well layer.

The first electrode is disposed on the first semiconductor layer of the first conductivity type.

The second electrode is disposed on the first semiconductor layer of the second conductivity type of the light emitting mesa structure part.

The ultraviolet light emitting element according to the present embodiment has the above-described configuration, and thereby the long life thereof is realized. Although this mechanism is not clear, it is presumed that this is due to the suppression of oxidation by oxygen in the air and deterioration by water vapor, which are factors of deterioration by providing the protective mesa structure part.

In addition, by surrounding the light emitting mesa structure part and the first electrode with the protective mesa structure part, it is possible to suppress the progress of oxidation or deterioration of the semiconductor that progresses from the chip end, and it is possible to further realize the long life.

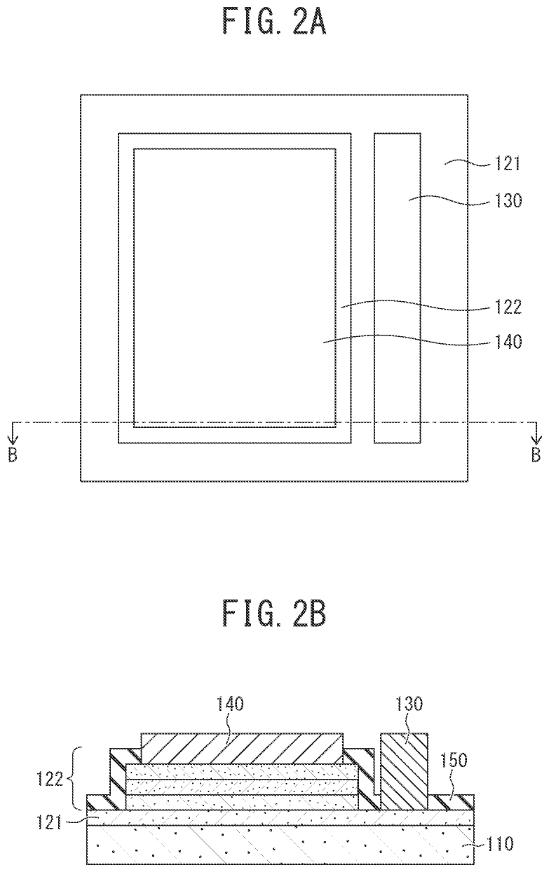

FIGS. 2A and 2B illustrate a planar structure (FIG. 2A) of the ultraviolet light emitting element in related art and a cross-sectional structure (FIG. 2B) in a B-B cross section of the conventional ultraviolet light emitting element illustrated in FIG. 2A. The ultraviolet light emitting element in related art illustrated in FIGS. 2A and 2B is formed of a substrate 110, a first semiconductor layer 121 of the first conductivity type, a light emitting mesa structure part 122, a first electrode 130, a second electrode 140, and an insulating layer 150. As illustrated in FIGS. 2A and 2B, the ultraviolet light emitting element in related art also includes a protective film 150 so that surfaces of the light emitting mesa structure part 122 and the first semiconductor layer 121 of the first conductivity type are not in direct contact with the atmosphere. However, even when compared with the ultraviolet light emitting element in related art, the long life of the ultraviolet light emitting element 1 according to the present embodiment including the protective mesa structure part 23 is remarkably excellent.

Since the protective mesa structure part may have the same layer configuration as the light emitting mesa structure part, there is a case where it is preferable from the viewpoint that it is possible to realize the long life without causing an additional process in the manufacturing process.

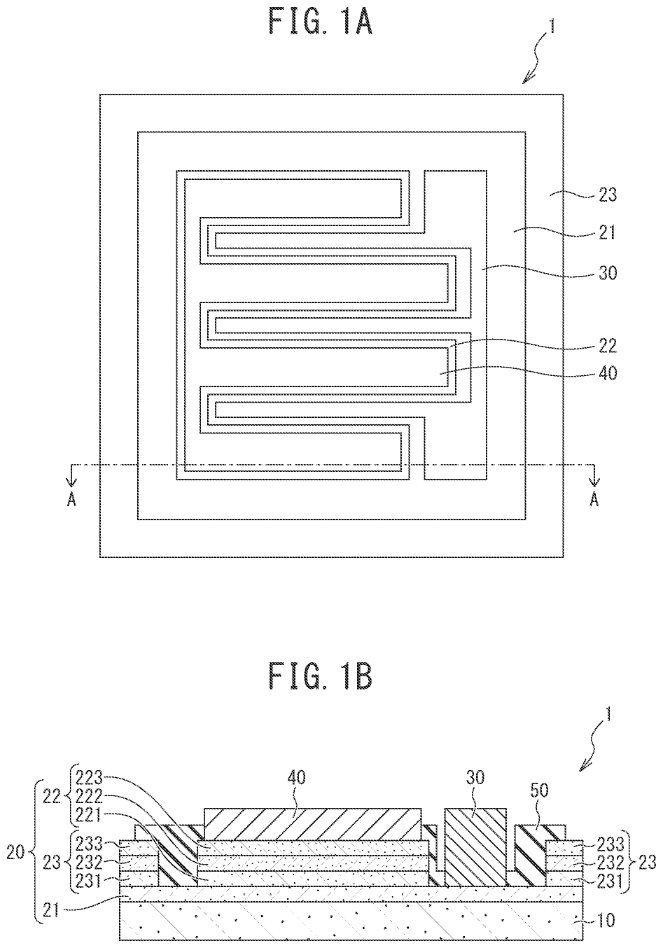

Hereinafter, a specific configuration example of the ultraviolet light emitting element 1 will be described with reference to FIG. 1.

FIG. 1A and FIG. 1B are schematic views for describing the ultraviolet light emitting element 1 according to the present embodiment. FIG. 1A is a schematic plan view illustrating a planar structure of the ultraviolet light emitting element 1, and FIG. 1B is a schematic sectional view illustrating a cross-sectional structure in an A-A cross section of the ultraviolet light emitting element 1 illustrated in FIG. 1A.

The ultraviolet light emitting element 1 according to the present embodiment includes a substrate 10, a nitride semiconductor laminate 20 disposed on the substrate 10, a first electrode 30, a second electrode 40, and an insulating layer 50. In addition, in FIG. 1A, the insulating layer 50 is not illustrated in order to facilitate the description of the planar configuration of the ultraviolet light emitting element 1.

The nitride semiconductor laminate 20 has a first semiconductor layer 21 of the first conductivity type, a light emitting mesa structure part 22 disposed on the first semiconductor layer 21 of the first conductivity type, and a protective mesa structure part 23 that is disposed on the first semiconductor layer 21 of the first conductivity type and spatially separated from the light emitting mesa structure part 22.

The light emitting mesa structure part 22 has a second semiconductor layer 221 of the first conductivity type, a first quantum well layer 222 disposed on the second semiconductor layer of the first conductivity type, and a first semiconductor layer 223 of the second conductivity type that is disposed on the first quantum well layer 222.

In addition, the protective mesa structure part 23 has a third semiconductor layer 231 of the first conductivity type, a second quantum well layer 232 disposed on the third semiconductor layer of the first conductivity type, and a second semiconductor layer 233 of the second conductivity type that is disposed on the second quantum well layer 232.

The first electrode 30 is disposed on the first semiconductor layer 21 of the first conductivity type.

The second electrode 40 is disposed on the first semiconductor layer 223 of the second conductivity type of the light emitting mesa structure part 22.

In the present embodiment, the insulating layer 50 covers a part of an upper surface of the protective mesa structure part 23 and a part of the first semiconductor layer 21 of the first conductivity type (a region in which none of the light emitting mesa structure part 22, the protective mesa structure part 23, and the first electrode 30 is disposed on an upper portion of the first semiconductor layer 21 of the first conductivity type).

Next, each component of the ultraviolet light emitting element 1 according to the present embodiment will be described in detail.

### <Substrate>

The substrate 10 is not particularly limited as long as the first semiconductor layer 21 of the first conductivity type can be formed on the substrate 10. Specific examples of the substrate 10 include sapphire, Si, SiC, MgO, Ga₂O₃, ZnO, GaN, InN, AlN, a mixed crystal substrate thereof, and the like.

The substrate 10 is preferably a single-crystal substrate whose bulk is a nitride semiconductor such as GaN, AlN, or AlGaN, or a nitride semiconductor layer (also referred to as a template) such as GaN, AlN, or AlGaN grown on a certain material, from the viewpoint that the difference in lattice constant from the first semiconductor layer 21 of the first conductivity type formed on the substrate 10 is small and that threading dislocations can be reduced by growing in a lattice-matched system, or from the viewpoint of increasing the lattice strain for hole gas generation. Further, the substrate 10 may contain impurities.

Further, from the viewpoint of improving light extraction, a surface of the substrate 10 opposite to a surface on which the first semiconductor layer 21 of the first conductivity type may be processed.

<Nitride Semiconductor Laminate>

The nitride semiconductor laminate 20 includes the first semiconductor layer 21 of the first conductivity type, the light emitting mesa structure part 22 disposed on the first semiconductor layer 21 of the first conductivity type, and the protective mesa structure part 23.

The light emitting mesa structure part 22 and the protective mesa structure part 23 have a mesa structure that protrudes from a part of the first semiconductor layer 21 of the first conductivity type. A method for forming the mesa structure is not particularly limited, and it is possible to form the mesa structure by laminating each layer using a known film forming device by using a method such as a molecular beam epitaxy (MBE) method or a metal organic chemical vapor deposition (MOCVD) method on the substrate 10, forming a mask pattern by a photolithography method, and etching a desired region by dry etching or wet etching.

The light emitting mesa structure part 22 and the protective mesa structure part 23 are spatially separated. Here, “spatially separated” means that a side surface of the light emitting mesa structure part 22 and a side surface of the protective mesa structure part 23 are present, and do not come into contact with each other.

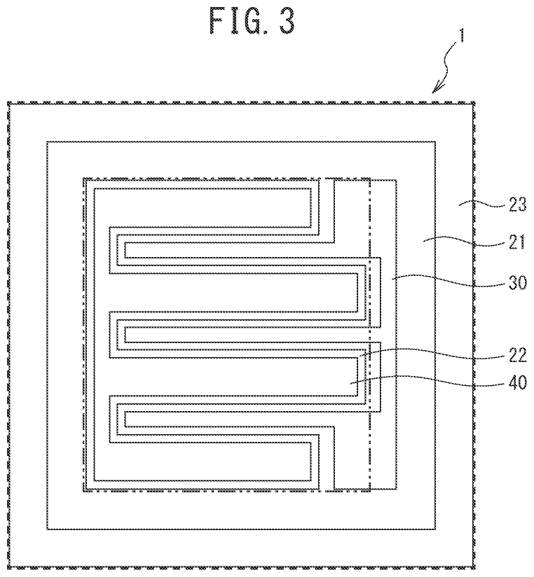

In order to realize the ultraviolet light emitting element 1 having a long life, it is preferable that the protective mesa structure part 23 is disposed to surround the light emitting mesa structure part 22 in plan view. Here, “disposed to surround” means that 90% or more of the sides of the smallest convex polygon that surrounds all of the light emitting mesa structure part 22 faces the side surface of the protective mesa structure part 23 in plan view. For example, FIG. 3 is a plan view illustrating, by a two-dot chain line, the side (outer peripheral line) of the smallest convex polygon that surrounds all of the light emitting mesa structure part 22 of the ultraviolet light emitting element 1 (see FIG. 1A). In FIG. 3, since all sides (100%) of the convex polygon indicated by the two-dot chain line face the side surface of the protective mesa structure part 23 (inner side of the protective mesa structure part 23 in FIG. 3), it can be said that the protective mesa structure part 23 is disposed around the light emitting mesa structure part 22 in plan view.

In addition, if the minimum convex polygon surrounding the protective mesa structure part 23 having one connection covers the electrodes in a plan view, it corresponds to “disposed to surround”. For example, FIG. 3 also illustrates a broken line which is the side of the smallest convex polygon (outer peripheral line) that surrounds the protective mesa structure part 23 of the ultraviolet light emitting element 1 (see FIG. 1A). In FIG. 3, since the convex polygon indicated by the broken line on the outer peripheral line covers the electrodes (the first electrode 30 and the second electrode 40), it can be said that the protective mesa structure part 23 is disposed to surround the light emitting mesa structure part 22 in plan view.

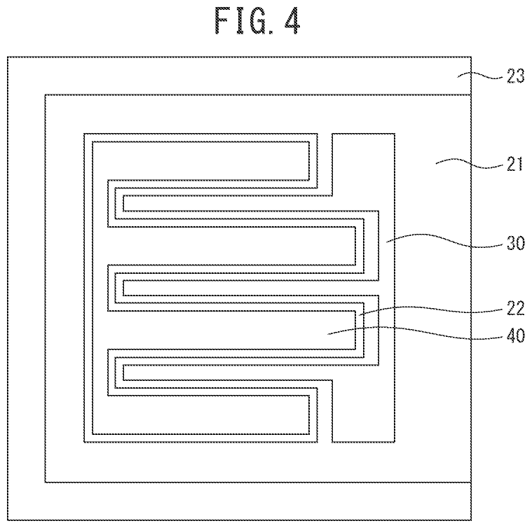

Specifically, not only in a case where the protective mesa structure part 23 of one connection is disposed on all four sides as illustrated in FIG. 1A, but also as illustrated in FIG. 4, there may be the side in which the protective mesa structure part 23 of one connection is not disposed. In the ultraviolet light emitting element illustrated in FIG. 4, the outer peripheral line of the smallest convex polygon surrounding the protective mesa structure part 23 of one connection is the outer shape of the ultraviolet light emitting element illustrated in FIG. 4 (the same shape as the broken line illustrated in FIG. 3), and since the minimum convex polygon covers the electrodes in plan view, it can be said that the protective mesa structure part 23 is disposed to surround the light emitting mesa structure part 22 in plan view.

The light emitting mesa structure part 22 is configured of the second semiconductor layer 221 of the first conductivity type, the first quantum well layer 222, and the first semiconductor layer 223 of the second conductivity type. The protective mesa structure part 23 is configured of the third semiconductor layer 231 of the first conductivity type, the second quantum well layer 232, and the second semiconductor layer 233 of the second conductivity type.

In the ultraviolet light emitting element according to the present embodiment, “first conductivity type” and “second conductivity type” mean that in a case where one is an n-type conductivity type, the other is a p-type conductivity type. That is, in a case where the nitride semiconductor layer of the first conductivity type is the n-type, the nitride semiconductor layer of the second conductivity type is the p-type. From the viewpoint of productivity and light emission efficiency, the nitride semiconductor layer of the first conductivity type is preferably the n-type.

In plan view, it is preferable that an end portion of a part of the protective mesa structure part 23 overlaps with an end portion of a part of the substrate 10, that is, the side surface of the protective mesa structure part 23 is disposed in substantially the same plane as the side surface of the substrate 10. Accordingly, for example, the protective mesa structure part 23 can cover the first semiconductor layer 21 of the first conductivity type to the outer peripheral portion of the chip, and can protect a wide region on the first semiconductor layer 21 of the first conductivity type. For example, in a case where an Al composition ratio of the first semiconductor layer 21 of the first conductivity type is high, the first semiconductor layer 21 of the first conductivity type tends to deteriorate easily. However, the Al composition of the second semiconductor layer 233 of the second conductivity type which is the uppermost layer is low, and protected by the protective mesa structure part 23 that is less likely to deteriorate, therefor the deterioration of the first semiconductor layer 21 of the first conductivity type can be suppressed by reducing the exposed area of the semiconductor layer 21 of the first conductivity type, and the ultraviolet light emitting element 1 having a long life can be realized. In addition, “overlapped” means that the deviation between a part of the end portion of the protective mesa structure part 23 and the end portion of the substrate 10 is 2 μm or less in plan view.

<Semiconductor Layer of First Conductivity Type>

The semiconductor layer of first conductivity type includes the first semiconductor layer 21 of the first conductivity type, the second semiconductor layer 221 of the first conductivity type, and the third semiconductor layer 231 of the first conductivity type.

As illustrated in FIG. 1B, the first semiconductor layer 21 of the first conductivity type is formed directly on the substrate 10. In addition, for the first semiconductor layer 21 of the first conductivity type, layers other than the first semiconductor layer 21 of the first conductivity type may be provided on the substrate 10 and the first semiconductor layer 21 of the first conductivity type may be provided thereon. Specifically, a buffer layer (not illustrated) may be provided on the substrate 10 and the first semiconductor layer 21 of the first conductivity type may be provided on the buffer layer.

It is preferable that the first semiconductor layer 21 of the first conductivity type, the second semiconductor layer 221 of the first conductivity type, and the third semiconductor layer 231 of the first conductivity type are formed of AlₓGa₁₋ₓN (x>0.3) and more preferably formed of AlₓGa₁₋ₓN (x>0.3) of n type. As a result, the light emission efficiency of the ultraviolet light emitting element 1 is improved.

<Quantum Well Layer>

The quantum well layer includes the first quantum well layer 222 and the second quantum well layer 232.

As illustrated in FIG. 1B, the first quantum well layer 222 is provided directly on the second semiconductor layer 221 of the first conductivity type and the second quantum well layer 232 is provided directly on the third semiconductor layer 231 of the first conductivity type. Further, the first quantum well layer 222 may be provided on a layer other than the quantum well layer provided on the second semiconductor layer 221 of the first conductivity type. Specifically, an AlGaN layer (not illustrated) not doped with impurities may be provided on the second semiconductor layer 221 of the first conductivity type and the first quantum well layer 222 may be provided on the AlGaN layer. In addition, in the same manner, the second quantum well layer 232 may be provided on the AlGaN layer or the like which is not doped with impurities formed on the third semiconductor layer 231 of the first conductivity type.

The first quantum well layer 222 and the second quantum well layer 232 are not particularly limited as long as they are nitride semiconductor layers, but are desirable to be a mixed crystal of AlN, GaN, and InN from the viewpoint of realizing high light emission efficiency. In addition to N, other V group elements such as P, As, and Sb and impurities such as C, H, F, O, Mg, and Si may be mixed into the first quantum well layer 222 and the second quantum well layer 232. Further, the first quantum well layer 222 and the second quantum well layer 232 may have a multiple quantum well structure or a single-layer quantum well structure, but are desirable to have at least two or more well structures from the viewpoint of realizing high light emission efficiency.

### <Semiconductor Layer of Second Conductivity Type>

The semiconductor layer of second conductivity type includes the first semiconductor layer 223 of the second conductivity type and the second semiconductor layer 233 of the second conductivity type.

As illustrated in FIG. 1B, the first semiconductor layer 223 of the second conductivity type is directly formed on the first quantum well layer 222, and the second semiconductor layer 233 of the second conductivity type is directly formed on the second quantum well layer 232. In addition, the first semiconductor layer 223 of the second conductivity type may be provided on a layer other than the semiconductor layer of the second conductivity type provided on the third semiconductor layer 231 of the first conductivity type. Specifically, a gradient composition layer (not illustrated) in which the ratio of constituent elements is continuously or discretely changed is provided on the first quantum well layer 222, and the first semiconductor layer 223 of the second conductivity type may be provided on the gradient composition layer. In addition, in the same manner, the second semiconductor layer 233 of the second conductivity type may be provided on the composition gradient layer or the like provided on the second quantum well layer 232.

Further, a barrier layer having a relatively large bandgap may be further provided between the gradient composition layer and the first semiconductor layer 223 of the second conductivity type or the second semiconductor layer 233 of the second conductivity type.

When the ratio of the Al element to the constituent elements on the uppermost surfaces of the first semiconductor layer 223 of the second conductivity type and the second semiconductor layer 233 of the second conductivity type is increased, a chemical reaction with oxygen or water vapor in the air is promoted and deterioration is likely to occur. Therefore, in order to realize the ultraviolet light emitting element 1 having a long life, it is preferable that the ratio of Al to the constituent elements of the uppermost surfaces of the first semiconductor layer 223 of the second conductivity type and the second semiconductor layer 233 of the second conductivity type is low. Specifically, it is preferable that the first semiconductor layer 223 of the second conductivity type and the second semiconductor layer 233 of the second conductivity type are formed in Al_{y}Ga_{1-y}N (y≤0.2).

### <First Electrode and Second Electrode>

The first electrode 30 and the second electrode 40 are provided to supply power to the ultraviolet light emitting element 1. The first electrode 30 is formed on the upper surface of the first semiconductor layer 21 of the first conductivity type, and the second electrode 40 is formed on the upper surface of the first semiconductor layer 223 of the second conductivity type of the light emitting mesa structure part 22.

Each electrode is formed of a conductive material, for example, gold, nickel, aluminum, titanium, a combination thereof, or the like. Each electrode includes, for example, an alloy layer (typically used for p-type contacts) of Ni and Au or a layer (typically used for n-type contact) in which Ti, Al, Ni, and Au are laminated. Such electrodes are formed, for example, by sputtering or vapor deposition.

Each electrode may also include a UV (ultraviolet) reflector. The UV reflector is a structure for preventing photons from escaping from the semiconductor layer structure by reorientating photons that emit light toward the electrode. In addition, the UV reflector is designed to improve the extraction efficiency of photons that are generated in the active region of the device by reorientating photons toward a desired light emitting surface, for example, a bottom surface.

### <Insulating Layer>

The insulating layer 50 covers a part or the entire surface of the upper surface of the protective mesa structure part 23. In addition, the insulating layer 50 covers at least a part of the first semiconductor layer 21 of the first conductivity type. The insulating layer 50 of the present embodiment covers a part of the upper surface of the protective mesa structure part 23 and a part of the first semiconductor layer 21 of the first conductivity type (region where any of the light emitting mesa structure part 22, the protective mesa structure part 23, and the first electrode 30 is not disposed thereon). When the region where the insulating layer 50 covers the upper surface of the protective mesa structure part 23 or a part of the first semiconductor layer 21 of the first conductivity type is widened, the region where the semiconductor layer comes into contact with air or water vapor can be reduced, and thus the ultraviolet light emitting element 1 having a long life can be realized.

From the viewpoint of waterproofness and stress on the device, it is preferable to use silicon oxide and silicon nitride, or both for the insulating layer 50. The method for forming the insulating layer 50 is not particularly limited, and the insulating layer 50 can be formed by, for example, a plasma CVD (chemical vapor deposition) device, a sputtering device, a vacuum deposition device, or the like. In a case where a silicon nitride film is produced as the insulating layer 50 by a plasma CVD device, a method of using monosilane (SiH₄) as a supply gas of silicon as a constituent element and ammonia (NH₃) as a supply gas of nitrogen is widely known. Further, in a case where the silicon oxide film is produced as the insulating layer 50 by the plasma CVD device, a method using monosilane (SiH₄) as a supply gas of silicon as a constituent element and nitrous oxide (N₂O) as a supply gas of oxygen is widely known.

In addition, from the viewpoint of productivity and stress on the device, the film thickness of the insulating layer 50 is preferably 10 nm or more and 1000 nm or less, and more preferably 50 nm or more and 500 nm or less.

In addition, from the viewpoint of further improving the waterproofness and suppressing the peeling of the insulating layer 50, another insulating layer, a metal layer, or the like may be disposed on the insulating layer 50.

### (1.2) Effects of Ultraviolet Light Emitting Element According to the Present Embodiment

The above-described ultraviolet light emitting element has the following effects.
(1) The ultraviolet light emitting element has the light emitting mesa structure part and the protective mesa structure part spatially separated from the light emitting mesa structure part as a nitride semiconductor laminate disposed on the substrate.

As a result, it is possible to suppress oxidation by oxygen in the air, deterioration due to water vapor, and the like, which are deterioration factors of the ultraviolet light emitting element, and to extend the life of the ultraviolet light emitting element.
(2) In the ultraviolet light emitting element, it is preferable that the protective mesa structure part is disposed to surround the light emitting mesa structure part and the first electrode in plan view.

Accordingly, it is possible to suppress the progress of oxidation and deterioration of the semiconductor that progresses from the chip end including the electrode, and it is possible to realize further a long life of the ultraviolet light emitting element.
(3) In the ultraviolet light emitting element, it is preferable that the protective mesa structure part is formed so that an end portion of a part of the protective mesa structure part overlaps with an end portion of a part of the substrate in plan view.

As a result, the protective mesa structure part can cover up to the outer peripheral portion of the chip, and the life of the ultraviolet light emitting element can be further extended.
(4) In the ultraviolet light emitting element, it is preferable that the first semiconductor layer of the first conductivity type, the second semiconductor layer of the first conductivity type, and the third semiconductor layer of the first conductivity type are formed of AlₓGa₁₋ₓN (x>0.3).

As a result, the light emission efficiency of the ultraviolet light emitting element is improved.
(5) In the ultraviolet light emitting element, it is preferable that the upper surfaces of the first semiconductor layer of the second conductivity type and the second semiconductor layer of the second conductivity type are formed of Al_{y}Ga_{1-y}N (y≤0.2).

As a result, since the ratio of the Al element to the constituent elements of the uppermost surface of the semiconductor layer is small, and chemical reactions with oxygen and water vapor in the air are less likely to occur, deterioration is less likely to occur, and the life of the ultraviolet light emitting element can be extended.
(6) It is preferable that the ultraviolet light emitting element includes the insulating layer that covers a part or the entire surface of the upper surface of the protective mesa structure part.

As a result, since the region in which the semiconductor layer comes into contact with air or water vapor can be reduced, the life of the ultraviolet light emitting element can be extended.
(7) In the ultraviolet light emitting element, it is preferable that at least a part of the first semiconductor layer of the first conductivity type is covered with the insulating layer.

As a result, since the region in which the semiconductor layer comes into contact with air or water vapor can be reduced, the life of the ultraviolet light emitting element can be extended.
(8) In the ultraviolet light emitting element, it is preferable that the insulating layer is formed of silicon oxide or silicon nitride.

As a result, the waterproofness of the ultraviolet light emitting element is improved.

### EXAMPLES

Hereinafter, the present disclosure will be described more specifically with reference to Examples and Comparative Examples. The ultraviolet light emitting element according to the present disclosure is not limited to the following Examples.

### Example 1

The ultraviolet light emitting element of Example 1 is an ultraviolet light emitting element having the structure according to the embodiment and has the following configurations.

The substrate is an AlN substrate.

The first semiconductor layer of the first conductivity type is a layer of an n-type Al_{0.7}Ga_{0.3}N (n-Al_{0.7}Ga_{0.3}N) containing Si of 2.0×10²⁰ cm⁻³ as an impurity and the thickness of the first semiconductor layer of the first conductivity type is 400 nm.

The light emitting mesa structure part is configured of the second semiconductor layer of the first conductivity type having a thickness of 150 nm, the first quantum well layer having a thickness of 70 nm, and the first semiconductor layer of the second conductivity type having a thickness of 10 nm. In addition, the protective mesa structure part is configured of the third semiconductor layer of the first conductivity type having a thickness of 150 nm, the second quantum well layer having a thickness of 70 nm, and the second semiconductor layer of the second conductivity type having a thickness of 10 nm.

The second semiconductor layer of the first conductivity type and the third semiconductor layer of the first conductivity type are formed of an n-Ala_{0.7}Ga_{0.3}N layer containing Si of 2.0×10²⁰ cm⁻³ as an impurity. The first quantum well layer and the second quantum well layer are formed by alternately laminating 5 layers of Al_{0.51}Ga_{0.49}N (well layer) having a thickness of 3 nm and Al_{0.78}Ga_{0.22}N (barrier layer) containing Si having a thickness of 11 nm as an impurity. The first semiconductor layer of the second conductivity type and the second semiconductor layer of the second conductivity type are formed of a p-type GaN (p-GaN) layer containing Mg of 2.0×10²⁰ cm⁻³ as an impurity.

The first electrode is a layer in which Ti, Al, Ni, and Au are laminated in this order.

The second electrode is a layer in which Ni and Au are laminated in this order.

The insulating layer is a silicon nitride layer and has a film thickness of 240 nm.

The ultraviolet light emitting element of Example 1 was manufactured by the following method.

First, the n-Al_{0.7}Ga_{0.3}N layer containing Si of 2.0×10²⁰ cm⁻³ as an impurity was formed at a thickness of 550 nm on the AlN substrate formed of the AlN single crystal.

Next, Al_{0.51}Ga_{0.49}N having a thickness of 3 nm and Al_{0.78}Ga_{0.22}N containing Si having a thickness of 11 nm as an impurity were laminated alternately with 5 layers each for a total of 70 nm on the n-Al_{0.7}Ga_{0.3}N layer.

Subsequently, these layers which are formed of a p-GaN layer having a thickness of 10 nm containing Mg of 2.0×10²⁰ cm⁻³ as an impurity were formed into a film by the organic metal vapor phase growth method (MOCVD method).

As described above, the laminate formed of the nitride semiconductor layer was formed on the AlN substrate.

Next, the laminate on the AlN substrate was subjected to dry etching to remove, at a predetermined depth, a region other than the regions serving as the light emitting mesa structure part and the protective mesa structure part of the laminate, and the n-Al_{0.7}Ga_{0.3}N layer was partially exposed. As a result, the laminate was formed in a shape in which the light emitting mesa structure part and the protective mesa structure part protrude from the first semiconductor layer of the first conductivity type having a thickness of 400 nm. This dry etching was performed using a chlorine-based gas after a resist pattern was formed on the laminate by a photolithography method. The chip of Example 1 had a square shape, the chip size was 855 μm on each side, and the protective mesa structure part was formed in a region from the outer periphery of the chip to 20 μm inside.

Next, Ti, Al, Ni, and Au were sequentially formed on a part of the exposed first semiconductor layer of the first conductivity type by using an electron beam vapor deposition method to form the first contact electrode. In addition, in the same manner, Ni and Au were sequentially formed on a part of the first semiconductor layer of the second conductivity type of the light emitting mesa structure part using an electron beam vapor deposition method to form a second contact electrode.

Next, silicon nitride having a thickness of 240 nm was formed by a plasma CVD method to cover the entire (all of upper surface and side surfaces) on the AlN substrate on which the light emitting mesa structure part, the protective mesa structure part, the first contact electrode, and the second contact electrode were formed.

Next, using a resist pattern formed by the photolithography method, contact holes were formed at predetermined positions (an upper surface of the first contact electrode and a part of the upper surface of the second contact electrode) of the silicon nitride by etching with CF₄. Next, in each of the formed contact holes, Ti having a thickness of 20 nm and Au having a thickness of 1000 nm were deposited in this order to form the first pad electrode and the second pad electrode. As a result, the first electrode formed of the first contact electrode and the first pad electrode, and the second electrode formed of the second contact electrode and the second pad electrode were formed. The steps up to this point were performed in a wafer state.

Finally, the wafer was individualized by laser dicing, and a sub-mount was flip-chip mounted by the Gold to Gold Interconnection (GGI) method and packaged.

In order to confirm the presence or absence of deterioration in the high humidity environment, the obtained ultraviolet light emitting element of Example 1 was subjected to a continuous energization test (250 mA) under an environment of 55° C. and 85% RH. In general, when the nitride semiconductor containing Al reacts with oxygen or water vapor in the air and deteriorates, the resistance of the semiconductor increases, and an increase in the drive voltage of the element is observed. Therefore, when the drive voltage of the element after the continuous energization test for 2000 hours was measured and a fluctuation rate of the drive voltage ((drive voltage after test)−(drive voltage before test)/drive voltage before test)) was evaluated, it was found that the fluctuation rate was 0%. In the ultraviolet light emitting element of Example 1, the drive voltage did not fluctuate, and no deterioration in appearance inside the protective mesa structure part was observed. That is, the ultraviolet light emitting element having a long life was obtained without increasing the resistance of the light emitting mesa structure part.

### Comparative Example 1

An ultraviolet light emitting element of Comparative Example 1 was obtained in the same manner as that of Example 1 except that when the laminate on the AlN substrate was dry-etched, only the light emitting mesa structure part was formed and the protective mesa structure part was not formed.

When the continuous energization test of the obtained ultraviolet light emitting element of Comparative Example 1 was performed in the same method as in Example 1, the fluctuation rate of the drive voltage after 2000 hours was +24%. In the ultraviolet light emitting element of Comparative Example 1, the drive voltage was increased, and deterioration occurred inside the light emitting mesa structure part in appearance.

From the above, it was found that the life of the ultraviolet light emitting element is extended by forming the protective mesa structure part together with the light emitting mesa structure part.

Although the embodiments of the present disclosure have been described above, the technical scope of the present disclosure is not limited to the technical scope described in the above-described embodiments. It is clear from the description of the scope of claims that various changes or improvements can be added to the above-described embodiments, and the forms to which such changes or improvements are added can also be included in the technical scope of the present disclosure.

### REFERENCE SIGNS LIST

1 ultraviolet light emitting element
10 substrate
20 nitride semiconductor laminate
21 first semiconductor layer of first conductivity type
22 light emitting mesa structure part
221 second semiconductor layer of first conductivity type
222 first quantum well layer
223 first semiconductor layer of second conductivity type
23 protective mesa structure part
231 third semiconductor layer of first conductivity type
232 second quantum well layer
233 second semiconductor layer of second conductivity type
30 first electrode
40 second electrode
50 insulating layer

1. An ultraviolet light emitting element comprising:
a substrate;
a nitride semiconductor laminate disposed on the substrate; and
a first electrode and a second electrode,
wherein the nitride semiconductor laminate includes a first semiconductor layer of a first conductivity type, a light emitting mesa structure part disposed on the first semiconductor layer of the first conductivity type, and a protective mesa structure part that is disposed on the first semiconductor layer of the first conductivity type and is spatially separated from the light emitting mesa structure part,
the light emitting mesa structure part includes a second semiconductor layer of the first conductivity type, a first quantum well layer disposed on the second semiconductor layer of the first conductivity type, and a first semiconductor layer of a second conductivity type disposed on the first quantum well layer,
the protective mesa structure part includes a third semiconductor layer of the first conductivity type, a second quantum well layer disposed on the third semiconductor layer of the first conductivity type, and a second semiconductor layer of the second conductivity type disposed on the second quantum well layer,
the first electrode is disposed on the first semiconductor layer of the first conductivity type,
the second electrode is disposed on the first semiconductor layer of the second conductivity type of the light emitting mesa structure part, and
the protective mesa structure part is disposed to surround the light emitting mesa structure part and the first electrode in plan view.

2. The ultraviolet light emitting element according to claim 1,
wherein an end portion of a part of the protective mesa structure part overlaps with an end portion of a part of the substrate in plan view.

3. The ultraviolet light emitting element according to claim 1,
wherein the first semiconductor layer of the first conductivity type, the second semiconductor layer of the first conductivity type, and the third semiconductor layer of the first conductivity type are formed of AlₓGa₁₋ₓN (x>0.3).

4. The ultraviolet light emitting element according to claim 1,
wherein upper surfaces of the first semiconductor layer of the second conductivity type and the second semiconductor layer of the second conductivity type are formed of Al_{y}Ga_{1-y}N (y≤0.2).

5. The ultraviolet light emitting element according to claim 1, comprising:
an insulating layer that covers a part or an entire surface of an upper surface of the protective mesa structure part.

6. The ultraviolet light emitting element according to claim 5,
wherein the insulating layer covers at least a part of the first semiconductor layer of the first conductivity type.

7. The ultraviolet light emitting element according to claim 5,
wherein the insulating layer is formed of silicon oxide or silicon nitride.
